(19) United States
(12) Patent Application Publication
(10) Pub. No.: US 2018/0364313 A1
(43) Pub. Date: Dec. 20, 2018

(54) Power Contactor and Method for Checking the Function of a Power Contactor

(71) Applicant: EPCOS AG, München (DE)

(72) Inventors: Robert HOFFMANN, Berlin (DE); Wolfgang SCHREIBER-PRILLWITZ, Fröndenberg (DE); Carsten DEHOFF, Berlin (DE); Wolfgang DÄUMER, Zeuthen (DE)

(21) Appl. No.: 16/060,360

(22) PCT Filed: Aug. 16, 2016
(86) PCT No.: PCT/EP2016/069441

§ 371 Date: Jun. 7, 2018

(30) Foreign Application Priority Data
Dec. 7, 2015 (DE) 10 2015 121 264.1

(51) Int. Cl. G01R 31/36; G01R 35/00; G01R 15/20; G01R 31/327; H01H 9/54

(52) U.S. Cl. CPC G01R 31/3696; G01R 35/005; B60L 3/0046; G01R 31/327; H01H 9/54; G01R 15/207

(57) ABSTRACT

A power contactor and a method for checking a functioning of a power contactor are disclosed. In an embodiment a power contactor includes a first electrical contact, a second electrical contact, a switching element configured to assume an open position and a closed position, wherein, in the closed position, the switching element connects the first electrical contact and the second electrical contact to one another, and wherein, in the open position, the first electrical contact and the second electrical contact are insulated from one another and a current sensor integrated into the power contactor, wherein the current sensor is configured to detect a current intensity of a current flowing through the power contactor.

This patent application is a national phase filing under section 371 of PCT/EP2016/069441, filed Aug. 16, 2016, which claims the priority of German patent application 10 2015 121 264.1, filed Dec. 7, 2015, each of which is incorporated herein by reference in its entirety.

### TECHNICAL FIELD

The present invention relates to a power contactor. Power contactors are electrically operated switches that can be actuated remotely. They have a control circuit, which can switch a load circuit on and off.

### BACKGROUND

A possible application of power contactors is the opening and isolating of battery circuits in electric motor vehicles. In this case, both the positive and the negative contact of a battery are generally isolated with the aid of a power contactor. The separation is effected in the rest state of the vehicle and in the event of a fault, for example, an accident. In this case, it is the main task of the power contactor to switch the vehicle to zero voltage and to interrupt the flow of current.

The flow of current via the power contactor is monitored in the vehicle with the aid of a current sensor, which can be housed in a box connected upstream of the battery as a further component in addition to the power contactor. This box is referred to as a BDU (battery disconnect unit). The current sensor has to fulfill two tasks in the box: During normal operation, the current sensor provides the present flow of current as a measurement value for the purpose of control, that is to say the power output of the battery to the motor or the power consumption of the generator to the battery. This measurement value is of central importance for the control of the vehicle motor. The second function is ensuring the functional safety of the battery unit, that is to say the unambiguous clarification of whether a potentially dangerous current is flowing through the power contactor. Here, this may be, for example, a high current intensity outside of the normal operating parameters, which is present as a result of an accident or another fault.

### SUMMARY OF THE INVENTION

Embodiments of the invention provide an improved power contactor, which has, for example, a lower space requirement. Further embodiments provide an improved method for testing the functioning of a power contactor.

Various embodiments provide a power contactor, which has a first electrical contact, a second electrical contact, a switching element and a current sensor integrated into the power contactor. The switching element can assume an open position and a closed position, wherein, in the closed position, the switching element connects the first electrical contact and the second electrical contact to one another and wherein the first electrical contact and the second electrical contact are insulated from one another when the switching element is situated in the open position. The current sensor integrated into the power contactor is designed to detect a current intensity of a current flowing through the power contactor.

The current sensor can be designed, in particular, to determine a current intensity of a current flowing in the load circuit. The load circuit is led through the electrical contacts. The switching element can be arranged in a control circuit. If the switching element is in its closed state, the load circuit is closed and a current can flow via the load circuit. If the switching element is changed to the open state, the load circuit is interrupted thereby.

Through the integration of the current sensor into the power contactor, the current sensor and the power contactor form one single functional unit. They can be produced together and coordinated with one another. The sensor can thus be calibrated in such a way that it can take into account magnetic fields generated by the power contactor, with the result that the magnetic fields do not distort the measurements of the current sensor. The mounting of the power contactor and the current sensor, for example, in a battery disconnect unit, is also simplified significantly, since these components can now be mounted together as one unit.

The current sensor can be referred to as being integrated into the power contactor when the power contactor and the current sensor are arranged in direct spatial proximity to one another. In particular, the power contactor and the current sensor can be surrounded by a joint housing. Further elements can be provided in the joint housing besides the power contactor and the current sensor. As an alternative, the housing can be free of further elements.

The power contactor and the current sensor can be produced together. The power contactor and the current sensor can be delivered to a user as a joint unit. Due to the high degree of integration, hardly any additional installation space is required for the current sensor. As a result, the power contactor comprising the integrated current sensor can be advantageous, in particular, in applications in which only a very limited space is available.

The first and the second electrical contact can be arranged in a load circuit, wherein the power contactor is designed to detect a current intensity of a current flowing through the load circuit. The load circuit can be, for example, the battery circuit of an electric vehicle. As already mentioned above, the determination of the current intensity in the battery circuit is of significant importance both as control variable for the purpose of controlling a vehicle motor and for monitoring the functional safety of the electric vehicle.

The current sensor can have a Hall sensor. The Hall sensor can utilize the Hall effect to measure the current intensity by virtue of it determining a magnetic field that surrounds a conductor through which current flows.

The current sensor can surround one of the electrical contacts. The electrical contacts can have, for example, a connection pole, which is surrounded by the current sensor. In this case, the Hall sensor can directly infer a current intensity of the current flowing through the electrical contact.

As an alternative or in addition, the current sensor can have a shunt resistor. In a shunt resistor, a current intensity flowing through the resistor can be identified by virtue of the voltage dropped across the resistor being determined. The current sensor can be interconnected in series with one of the electrical contacts.

If the current sensor integrated into the power contactor has both a Hall sensor and a shunt resistor, the current intensity can be determined by means of two measurement methods that are independent of one another. Particularly in safety-relevant applications, for instance in an electric motor vehicle, this increased measure of safety is of significant importance. It can thus be ensured that the current can still be measured and, where necessary, can be switched off even in the case of a partial failure of the sensor.

The power contactor can have an interface by means of which the data detected by the current sensor can be read out. In this way, the measurement data detected by the current sensor can be transmitted, for example, to an external control unit. The external control unit can then use the measurement data detected by the current sensor with respect to the current intensity to decide whether the power contactor should be isolated. The external control unit can actuate the power contactor.

The current sensor can be calibrated in such a way that magnetic fields generated by the power contactor can be taken into account in the measurement of the current intensity. The power contactor can have, for example, a coil and/or a deflection magnet, which can each generate a magnetic field. As a result of the fact that the magnetic fields can be taken into account in the calibration of the current sensor, the measurement accuracy of the sensor can be significantly improved.

Further embodiments provide a method for testing the functioning of a power contactor. In this case, the power contactor can be, in particular, the power contactor described above. Accordingly, all the functional and structural features that have been disclosed in connection with the power contactor can also apply to the method. According to the method, a calibration step of the current sensor and a functional test of the switching element are performed at the same time. In the calibration step, disturbance effects can be detected, which would adversely affect the measurement accuracy of the current sensor. These include, in particular, magnetic fields generated by the power contactor. Since calibration of the sensor and functional tests of the power contactor are performed together and, in particular, before distribution of the component, these steps no longer have to be performed when the power contactor is installed. As a result, the mounting outlay for a user is significantly reduced.

During the calibration step of the current sensor, magnetic fields generated by the switching element and/or by the electrical contacts can be identified and taken into account in the calibration of the current sensor.

### BRIEF DESCRIPTION OF THE DRAWINGS

The present invention is described in more detail in the following text with reference to the figures.

FIG. 1 shows a perspective view of the power contactor 1;

FIG. 2 shows a front view of a cross section through the power contactor 1; and

FIG. 3 shows a perspective view of the cross section shown in FIG. 2.

### DETAILED DESCRIPTION OF ILLUSTRATIVE EMBODIMENTS

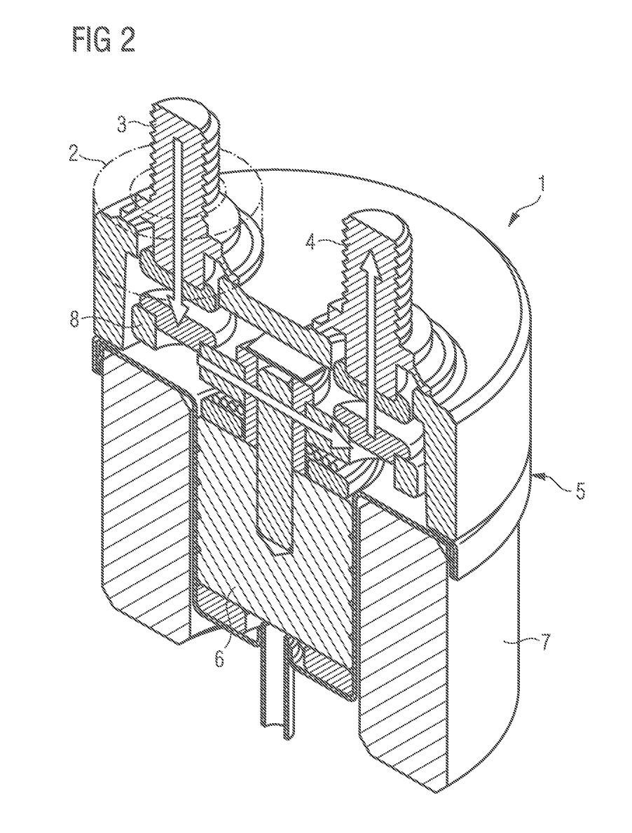

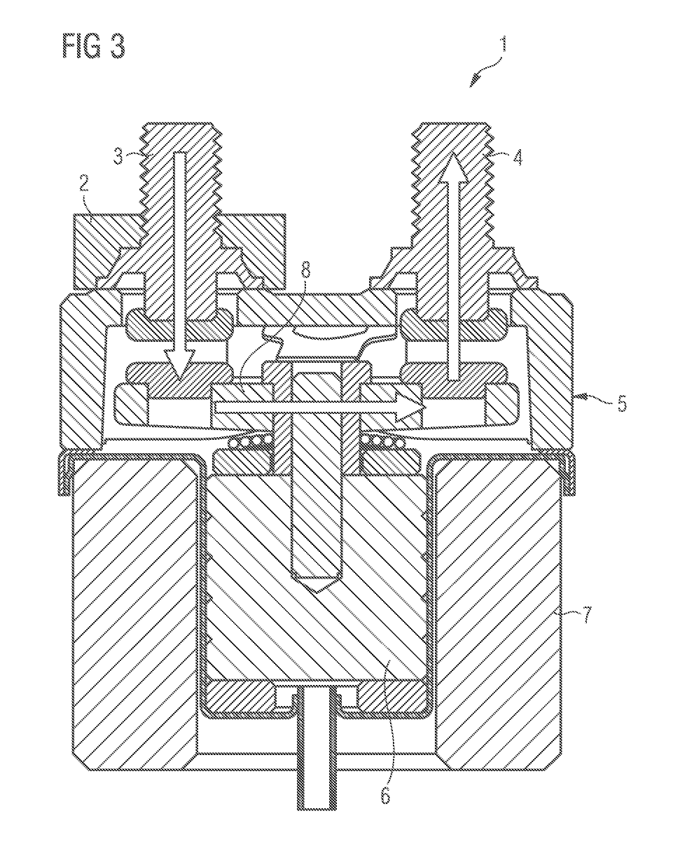

The power contactor 1 is an electrically operated switch that can be actuated remotely. The power contactor 1 has a first electrical contact 3 and a second electrical contact 4. The power contactor 1 also has a switching element 5. The switching element 5 can assume an open position and a closed position. In FIGS. 2 and 3, the switching element 5 is shown in each case in its open position. In the open position, the switching element 5 does not connect the two electrical contacts 3, 4 to one another so that the electrical contacts 3, 4 are insulated from one another. Accordingly, no current can flow via the power contactor 1 when the switching element 5 is situated in its open position.

The switching element 5 can also assume a closed position. In the closed position, the switching element 5 conductively connects the two electrical contacts 3, 4 to one another so that a current can flow via the power contactor 1.

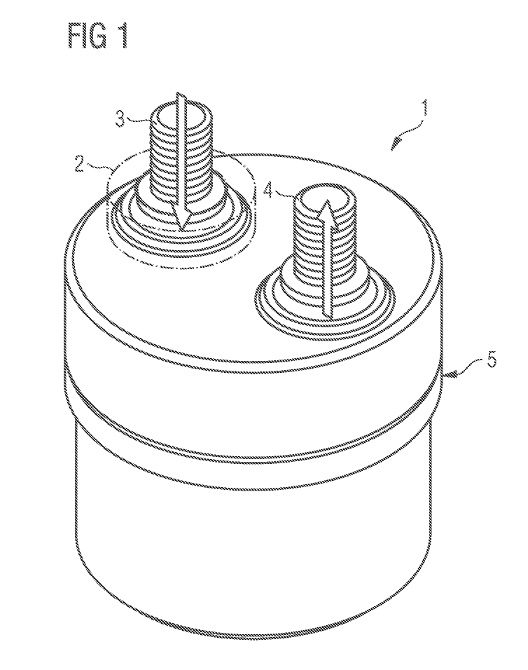

Two circuits are formed in the power contactor 1. These are a load circuit and a control circuit. The load circuit is closed when the switching element 5 is moved into the closed position. In FIGS. 1 to 3, arrows indicate a path along which the current in the load circuit flows when the switching element 5 is situated in the closed position.

The power contactor 1 is typically interconnected with further components by means of the load circuit. The power contactor 1 can be designed, in particular, to interrupt the load circuit when the further components are to be switched off.

The power contactor 1 can also comprise the control circuit. The control circuit is designed to actuate the switching element 5. The power contactor 1 is thus “controlled”, so to speak, by means of the control circuit. The control circuit makes it possible to close or to interrupt the load circuit by way of a movement of the switching element 5.

In the exemplary embodiment shown here, the switching element 5 has a coil 6, an iron core 7 and a bridge 8. The bridge 8 can assume an upper position and a lower position. The upper position of the bridge 8 corresponds to the closed position of the switching element 5. The lower position of the bridge 8 corresponds to the open position of the switching element 5.

If a current is flowing through the coil 6, the bridge 8 is consequently moved out of the iron core 7 and the coil 6. The bridge 8 is then situated in its upper position. In this position, the bridge 8 conductively connects the two electrical contacts 3, 4 to one another. If no current is flowing through the coil 6, the bridge 8 lowers to its lower position in which the two contact elements 3, 4 are not conductively connected to one another.

Electrical power contactors 1 that function according to a comparable principle can be used here in any manner. Furthermore, pneumatic power contactors are also possible.

The power contactor 1 also has the current sensor 2, which is integrated into the power contactor 1. Accordingly, the power contactor 1 and the current sensor 2 form one single functional unit. The current sensor 2 is designed to detect the current intensity of a current flowing through the load circuit.

In the present exemplary embodiment, the current sensor 2 has a Hall sensor. The Hall sensor has a core, which has a slotted ring shape and which surrounds the first electrical contact 3. A Hall element is located in the slot of the core. If a current now flows through the first electrical contact 3, the Hall element registers a change in the present magnetic fields since the current flowing through the first electrical contact induces a magnetic field. The Hall sensor can deduce the current intensity based on these changes in magnetic field.

The power contactor 1 can be interconnected with further components. To this end, the power contactor 1 can be connected to electrical lines, which are connected to the first and the second contact 3, 4. This subsequent connection of the first and the second contact 3, 4 can be performed entirely independently of the current sensor 2.

The current sensor 2 is designed in such a way that, in addition to the nominal currents usually to be expected in the power contactor 1, current peaks, which can be three times the nominal current, can also be measured with sufficient accuracy. With this measurement range of the integrated current sensor 2, the power contactor 1 can be used without further additions in applications with demands for functional safety.

The power contactor 1 also has an interface by means of which measurement values measured by the current sensor 2 can be read out. For example, the measurement values can be reported to a superordinate system by means of the interface.

The current sensor 2 is adjusted geometrically and electrically in such a way that it requires only minimal space. In particular, the current sensor 2 does not have to be mounted in a circuit arrangement and calibrated separately from the power contactor 1. Instead, the current sensor forms, together with the power contactor 1, one functional unit.

In an alternative exemplary embodiment, the current sensor 1 can have a shunt resistor, which is integrated into the power contactor 1. The current sensor 1 can detect a voltage dropped across the shunt resistor and identify the current intensity from this variable.

The shunt resistor makes it possible to measure the current intensity based on a different functional principle to the Hall sensor. It would also be conceivable for both a Hall sensor and a shunt resistor to be integrated into the power contactor 1 so that the current sensor 2 makes it possible to detect the current intensity based on two measurement principles that are independent of one another. In this way, the reliability of the measurement could be increased.

When the functioning of the power contactor 1 is tested, the current sensor 2 can be calibrated and a functional test of the switching element 5 can be performed at the same time. In particular, the current sensor 2 can be calibrated in such a way that magnetic fields, which are generated by other elements of the power contactor 1, such as the coil 6, for instance, can be taken into account in the calibration. The accuracy of the current sensor 2 can be increased in this way by way of its integration into the power contactor 1. Faults and error sources caused by the power contactor 1 can then no longer distort the measurement of the current intensity.

1-10. (canceled)

11. A power contactor comprising:
a first electrical contact;
a second electrical contact;
a switching element configured to assume an open position and a closed position, wherein, in the closed position, the switching element connects the first electrical contact and the second electrical contact to one another, and wherein, in the open position, the first electrical contact and the second electrical contact are insulated from one another; and
a current sensor integrated into the power contactor, wherein the current sensor is configured to detect a current intensity of a current flowing through the power contactor.

12. The power contactor according to claim 11,
wherein the first and second electrical contacts are arranged in a load circuit, and
wherein the power contactor is configured to detect a current intensity of a current flowing through the load circuit.

13. The power contactor according to claim 11, wherein the current sensor comprises a Hall sensor.

14. The power contactor according to claim 11, wherein the current sensor surrounds one of the electrical contacts.

15. The power contactor according to claim 11, wherein the current sensor comprises a shunt resistor.

16. The power contactor according to claim 11, wherein the current sensor is interconnected in series with one of the electrical contacts.

17. The power contactor according to claim 11, further comprising an interface configured to provide data detected by the current sensor.

18. The power contactor according to claim 11, wherein the current sensor is calibrated in such a way that magnetic fields generated by the power contactor are taken into account in a measurement of the current intensity.

19. A method for checking a functioning of a power contactor according to claim 11, the method comprising:
calibrating the current sensor; and
functionally testing the switching element,
wherein calibrating the current sensor and functionally testing the switching element are performed at the same time.

20. The method according to claim 19, wherein, during calibrating the current sensor, magnetic fields generated by the switching element and/or by the electrical contacts are identified and taken into account in calibrating the current sensor.
